(19) United States
(12) Patent Application Publication
(10) Pub. No.: US 2008/0160457 A1
(43) Pub. Date: Jul. 3, 2008

(54) APPARATUS AND METHOD FOR REDUCING DEFECTS

(76) Inventors: Sean Michael Collins, Richardson, TX (US); David C. Hall, Saratoga Springs, UT (US); Scott W. Jessen, Allen, TX (US)

Correspondence Address: TEXAS INSTRUMENTS INCORPORATED, P O BOX 655474, M/S 3999, DALLAS, TX, 75265, US

(21) Appl. No.: 11/617,243

(22) Filed: Dec. 28, 2006

(51) Int. Cl. G03B 27/68; G03F 7/20

(52) U.S. Cl. 430/322; 355/70; 355/66

(57) ABSTRACT

An embodiment relates generally to an apparatus for reducing defects. The apparatus includes a spindle adapted to hold a wafer; and at least two light sources configured to direct light to a top-side and a back-side of the wafer

### FIELD

This invention relates generally to semiconductor fabrication processing, more particularly to apparatus and methods for reducing defects in the semiconductor fabrication process.

### DESCRIPTION OF THE RELATED ART

Resists are generally proprietary mixtures of a polymer or its precursor and other small molecules, e.g., photoacid generators, that have been specially formulated for a given lithography technology. For a typical semiconductor fabrication process, the resist is spin coated on a semiconductor substrate such as a silicon wafer, to form a thin uniform layer. The resist layer may be baked at a low temperature to evaporate residual solvents. A latent image is formed in the resist by using ultraviolet light through a photomask with opaque and transparent regions or by direct writing using a laser beam or an electron beam. Areas of the resist that have (or have not) been exposed are removed by rinsing with an appropriate solvent. Subsequently, there is another bake and processing through the resist pattern: wet or dry etching, lift-off, doping, etc., as known to those skilled in the art. Finally, the resist is removed.

There are drawbacks and disadvantages associated with the previously described process. For example, resist accumulation on a bevel of the wafer in the photo track can cause yield loss, which is illustrated in FIG. 3. As shown in FIG. 3, the conventional edge exposure system 300 includes a single light source 305 with a fixed aperture focused on the area 330 that encompasses the edge 320 of the wafer 310, where the edge 320 may be a bevel 325. The wafer 310 may be supported by a spindle 315 that rotates the wafer 310 around the spindle 315.

During the resist coat process, the resist is spin coated to cover the top of the wafer 310. The resist spreads to the edge 320 and can also coat or partially coast the bevel 325 and back edge of the wafer 310. Since the single light source 305 directs light only to the top side of the wafer 310, the resist on the bottom half of the bevel and underneath the wafer are unexposed, and thus remain.

The remaining resist can break away on subsequent processing steps and become yield limiting defects. More particularly, the resist accumulation can be redistributed during subsequently processing. Moreover, the resist accumulation can cause blistering and de-lamination of deposited dielectrics and/or metals, which also contribute to yield loss. Accordingly, there is a need in the art to reduce the effects of resist accumulation.

### SUMMARY

An embodiment relates generally to an apparatus for reducing defects. The apparatus includes a wafer and a spindle configured to hold the wafer. The apparatus also includes multiple light sources configured to direct light to a top edge, a bevel, and a back-edge of the wafer.

Another embodiment pertains generally to a method of reducing defects. The method includes depositing a layer of resist on a wafer and directing light from multiple light sources on a top edge, a bevel, and a back-edge of the wafer to reduce the layer of resist.

Yet another embodiment relates generally to an apparatus for reducing defects. The apparatus includes a spindle adapted to hold a wafer; and at least two light sources configured to direct light to a top edge, a bevel, and a back-edge of the wafer.

### BRIEF DESCRIPTION OF THE DRAWINGS

Various features of the embodiments can be more fully appreciated, as the same become better understood with reference to the following detailed description of the embodiments when considered in connection with the accompanying figures, in which:

FIG. 1 depicts an exemplary bevel exposure system in accordance with an embodiment;

FIG. 2 depicts another exemplary bevel reduction system in accordance with another embodiment; and

FIG. 3 depicts a conventional bevel exposure system.

### DETAILED DESCRIPTION OF EMBODIMENTS

For simplicity and illustrative purposes, the principles of the present invention are described by referring mainly to exemplary embodiments thereof. However, one of ordinary skill in the art would readily recognize that the same principles are equally applicable to, and can be implemented in, all types of semiconductor fabrication systems, and that any such variations do not depart from the true spirit and scope of the present invention. Moreover, in the following detailed description, references are made to the accompanying figures, which illustrate specific embodiments. Electrical, mechanical, logical and structural changes may be made to the embodiments without departing from the spirit and scope of the present invention. The following detailed description is, therefore, not to be taken in a limiting sense and the scope of the present invention is defined by the appended claims and their equivalents.

Embodiments relate generally to apparatus and methods of reducing defects on a wafer induced by resist accumulation. More particularly, an edge exposure system may be configured to have light sources from multiple angles directed at a bevel and a back edge of a wafer as well as a top or front edge. The wafer may comprise of silicon or other similar material used in semiconductor manufacturing as known to those skilled in the art. On the edge or rim of the wafer, the rim of the wafer may comprise a top or front edge and a back or bottom edge, where a bevel may be formed between the edges.

In one embodiment, multiple light sources generating a broad frequency of light to activate the resist are configured to direct light to the front edge, the bevel, and back edge of the wafer. After exposure, the resist on the top edge, bevel, and back edge becomes soluble, which then can be removed by subsequent develop processes. In another embodiment, a light source may be configured with a mirror, waveguide, or light guide, positioned to reflect and/or direct the light towards the bevel and back edge. Unlike conventional systems where the remaining resist can break-away on subsequent processing steps and become yield limiting defects, the removal of the resist on the bevel and back edge.

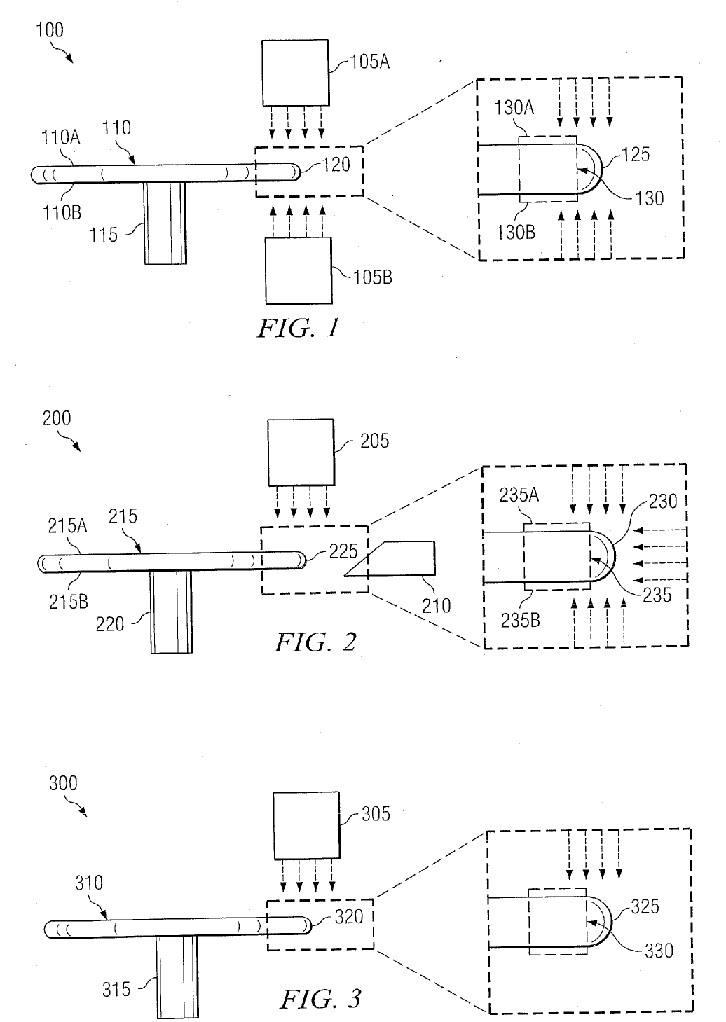

FIG. 1 depicts an exemplary edge exposure system 100 in accordance with an embodiment. It should be readily apparent to those of ordinary skill in the art that the edge exposure system 100 depicted in FIG. 1 represents a generalized schematic illustration and that other components may be added or existing components may be removed or modified.

As shown in FIG. 1, the edge exposure system 100 may include multiple light sources 105A and 105B, a wafer 110 and a spindle 115. The wafer 110 may be substrate where semiconductor fabrication can be directed thereon. The wafer 110 may be silicon or other substrate known to those skilled in the art of semiconductor processing. The spindle 115 may be configured to support the wafer 110 in a generally perpendicular to the paths of light from light sources 105A-B. The spindle 115 may include a platen (not shown) to support the wafer in some embodiments.

The wafer 110 may also comprise a top surface 110A and a bottom surface 110B along with an edge or rim 120. The rim 120 may comprise a top edge 130A, a back edge 130B and a bevel 125 formed between the edges 130A, 130B, respectively. The top edge 130A and the back-edge 130B may be an area determined by the user or by the requirements of the fabricated device.

The light source 105A may be aligned to direct light to the top edge 130A and a top half of the bevel 125. The light source 105B may be aligned to direct its light to the back edge 130B and a bottom half of the bevel 125. The frequency range of the light from light sources 105A-B may be broad to ensure activation of any applied resist. In some embodiments, the frequency range may from 440 nm to 193 nm. In other embodiments, the frequency range may change due to the type of resist being used. The illumination source may alternately be a monochromatic source, such as a laser, of a frequency appropriate to the resist being used in the system. This may be used instead of or in addition to a broadband source.

The light sources 105A-B may have a fixed aperture to focus the light. The width of the fixed aperture may range from 5 mm to 0.1 mm in accordance with some embodiments. In other embodiments, light sources 105A-B may be implemented as a fiber optic tip, a light source with a waveguide or other light sources that can focus a broad frequency of light to a small location. The light sources 105A-B may be positioned using support structures (not shown) as known to those skilled in the art.

Although the embodiment depicted in FIG. 1 shows two light sources aligned to direct light at the top and back edges along with the bevel, other embodiments may include a third or more light sources to direct light at the bevel. Yet other embodiments may configure the light sources at various angles to cover the top and back edges along with the bevel.

Accordingly, embodiments of the edge exposure system 100 can expose light to both edges 130A, 130B along with the bevel 125. The light may then make soluble substantially all the resist coating the top and back edges 130A, 130B of the bevel 125, which then can be removed by a subsequent develop process.

FIG. 2 illustrates another exemplary embodiment of the edge exposure system 200. It should be readily apparent to those of ordinary skill in the art that the bevel exposure system 200 depicted in FIG. 2 represents a generalized schematic illustration and that other components may be added or existing components may be removed or modified.

As shown in FIG. 2, the edge exposure system 200 may include light sources 205, a mirror 210, a wafer 215 and a spindle 220. The wafer 215 may be substrate where semiconductor fabrication can be directed thereon. The wafer 215 may be silicon or other substrate known to those skilled in the art. The spindle 120 may be configured to support the wafer 215 in a generally perpendicular to the paths of light from light sources 105A-B. The spindle 115 may include a platen (not shown) to support the wafer in some embodiments.

The wafer 215 may also comprise a top surface 215A and a bottom surface 215B along with an edge or rim 225. The rim 225 may comprise a top edge 235A, a back edge 235B and a bevel 230 formed between the edges 235A, 235B, respectively. The top edge 235A and the back-edge 235B may be an area determined by the user or by the requirements of the fabricated device.

The light source 205 may be aligned to direct its light to the top edge 235A and a top half of the bevel 230. The mirror 210 may be aligned to direct the light from the light source 205 to the bevel 230, the back edge 23B and/or a combination thereof depending on the configuration of mirror 205. The configurations of mirrors to direct light at the aforementioned areas are known to those skilled in the art. The frequency range of the light from light sources 205 may be broad to ensure activation of any applied resist. In some embodiments, the frequency range can be from 440 nm to 193 nm. In other embodiments, the frequency range may change due to the type of resist being used.

The light sources 205 may have a fixed aperture to focus the light. The width of the fixed aperture may range from 5 mm to 0.1 mm in accordance with some embodiments. In other embodiments, light source 205 may be implemented as a fiber optic tip, a light source with a waveguide or other light sources that can focus a broad frequency of light to a small location. The light source 205 and mirror 210 may be positioned using support structures (not shown) as known to those skilled in the art.

While the invention has been described with reference to the exemplary embodiments thereof, those skilled in the art will be able to make various modifications to the described embodiments without departing from the true spirit and scope. The terms and descriptions used herein are set forth by way of illustration only and are not meant as limitations. In particular, although the method has been described by examples, the steps of the method may be performed in a different order than illustrated or simultaneously. Those skilled in the art will recognize that these and other variations are possible within the spirit and scope as defined in the following claims and their equivalents.

What is claimed is:

1. An apparatus for reducing defects, the apparatus comprising:
a wafer;
a spindle configured to hold the wafer; and
multiple light sources configured to direct light to a top edge and a back-edge of the wafer.

2. The apparatus of claim 1, wherein the multiple light sources further comprises a lamp and a mirror.

3. The apparatus of claim 1, wherein the multiple light sources is further configured to direct light to a bevel edge of the wafer.

4. The apparatus of claim 1, further comprising a layer of resist on the wafer.

5. The apparatus of claim 4, wherein the frequency of the light from the multiple light sources is tuned to the layer of resist.

6. A method of reducing defects, the method comprising:
depositing a layer of resist on a wafer; and
directing light from multiple light sources on a top edge and a back-edge of the wafer to reduce the layer of resist.

7. The method of claim 6, wherein the multiple light sources further comprises a lamp and a mirror.

8. The method of claim 7, further comprising directing light from the multiple light sources to a bevel of the wafer.

9. The method of claim 6, wherein the frequency of the light from the multiple light sources is tuned to the layer of resist.

10. An apparatus for reducing defects, the apparatus comprising:
a spindle adapted to hold a wafer; and
at least two light sources configured to direct light to a top edge and a back-edge of the wafer.

11. The apparatus of claim 10, wherein the at least two light sources further comprises a lamp and a mirror.

12. The apparatus of claim 10, further comprising a wafer supported by the spindle.

13. The apparatus of claim 12, wherein the multiple light sources is further configured to direct light to a bevel of the wafer.

14. The apparatus of claim 10, further comprising a layer of resist on the wafer.

15. The apparatus of claim 14, wherein the frequency of the light from the multiple light sources is tuned to the layer of resist.

16. The apparatus of claim 10, wherein the at least two light sources each generate a broad band of light.

17. The apparatus of claim 10, wherein the at least two light sources each generate a monochromatic light.
